(19) United States
(12) Patent Application Publication
(10) Pub. No.: US 2012/0262202 A1
(43) Pub. Date: Oct. 18, 2012

(54) Output Buffer

(76) Inventors: Chien-Hsi Lee, Miaoli County (TW); Tung-Cheng Hsin, Hsinchu City (TW)

(21) Appl. No.: 13/444,870

(22) Filed: Apr. 12, 2012

(30) Foreign Application Priority Data
Apr. 15, 2011 (TW) 100113136

(51) Int. Cl. H03K 19/0175

(52) U.S. Cl. 326/63

(57) ABSTRACT

An output buffer includes a level conversion module for generating a first logic signal having a first level range and a second logic signal having a second level range, a pre-driving module composed of low-voltage transistors for generating a first control signal and a second control signal according to the first logic signal and the second logic signal, and an output module for generating an output signal having a third level range according to the first control signal and the second control signal. Each of the first and second level ranges is smaller than the third level range.

### BACKGROUND OF THE INVENTION

1. Field of the Invention

The present invention relates to an output buffer, and more particularly, to an output buffer having low output jitter.

2. Description of the Prior Art

Please refer to FIG. 1, which is a schematic diagram of an output buffer 10 according to the prior art. The output buffer 10 is often utilized in applications which require outputting a voltage signal to an external of an integrated circuit (IC). For example, in System-on-a-chip (SoC) applications, signals are outputted to a signal driving circuit for a memory device, e.g. Dynamic Random Access Memory (DRAM). As shown in FIG. 1, the output buffer 10 often includes an AND logic gate 100, level conversion units 102, 104, pre-driving units 110, 112, output transistor arrays 120_1-120_M, 122_1-122_M connected in parallel, and a resistor 130. The AND gate 100 performs an AND operation on an enable signal OE and a data signal DATA, to decide whether to transmit the data signal DATA as an input signal IN according to the enable signal OE. The input signal IN has a level range between an initial high voltage VDD and an initial low voltage VSS.

The level conversion units 102, 104 convert and amplify the input signal IN to a first logic signal LG1 and a second logic signal LG2, respectively, according to a predefined input-to-output conversion curve. Both the first logic signal LG1 and the second logic signal LG2 have level ranges between a first high voltage VDDQ and a first low voltage VSSQ, and satisfy the condition of VDDQ-VSSQ>VDD-VSS. The pre-driving units 110, 112 are composed of inverters or multi-stage amplifiers connected in series, and generate a first control signal CON1 and a second control signal CON2 according to the first logic signal LG1 and the second logic signal LG2, respectively. Finally, the output transistor arrays 120_1-120_M, 122_1-122_M connected in parallel generate an output signal OUT having a value between the first high voltage VDDQ and the first low voltage VSSQ according to the first control signal CON1 and the second control signal CON2, respectively. The resistor 130 is utilized to provide electrostatic discharge (ESD) delay protection.

The output transistor arrays 1201-120M, 1221-122M form an output stage directly facing the load, and are composed of high voltage thick oxide Complementary Metal-Oxide-Semiconductor (CMOS) transistors. Moreover, the pre-driving units 110, 112 are also high voltage CMOS components. However, there is a growing trend for lower operating voltages in high-speed interfaces, e.g. second generation Double-Data-Rate Synchronous Dynamic Random Access Memory (DDR2 SDRAM) interface uses an operating voltage of 1.8 v, and third generation DDR SDRAM (DDR3 SDRAM) interface lowers to 1.5 v, while low-voltage third generation DDR SDRAM (DDR3L SDRAM) further lowers to 1.35 v. Under such trends for lower output stage voltages from power supplies, driving currents from high-voltage transistors are lower, in turn generating a longer signal delay. At the same time, low operating voltages contribute to a relatively weak noise tolerance from power supplies during synchronous operations. This results in a larger output jitter in the output signal OUT.

Therefore, maintaining a stable output signal for output buffer while conforming to lower operating voltage trends has become a common goal for the industry.

### SUMMARY OF THE INVENTION

Therefore, a primary objective of the present invention is to provide an output buffer having a low output jitter.

An embodiment discloses an output buffer, comprising a level conversion module, for generating a first logic signal having a first level range and a second logic signal having a second level range according to an input signal; a pre-driving module, composed of low-voltage transistors, for generating a first control signal at a first node and generating a second control signal at a second node according to the first logic signal and the second logic signal; and an output module, coupled to the first node and the second node of the pre-driving module, for generating an output signal having a third level range at an output node according to the first control signal and the second control signal; wherein each of the first level range and the second level range is smaller than the third level range.

Another embodiment provides an output buffer, comprising: a level conversion module, for generating a first logic signal having a first level range and a second logic signal having a second level range according to an input signal; a pre-driving module, composed of low-voltage transistors, for generating a first control signal at a first node and generating a second control signal at a second node according to the first logic signal and the second logic signal; and an output module, coupled to the first node and the second node of the pre-driving module, for generating an output signal having a third level range at an output node according to the first control signal and the second control signal; wherein the first level range is different from the second level range, each of the first level range and the second level range is smaller than the third level range, and each of the first and second level ranges is substantially smaller than or equal to an initial level range of the input signal.

Further another embodiment discloses an output buffer, comprising: a level conversion module, comprising a level conversion unit for performing level conversion on an input signal to generate a first logic signal having a first level range; and a delay unit for delaying the input signal to generate a second logic signal having a second level range; a pre-driving module, comprising a first low-voltage pre-driving unit for generating a first control signal at a first node according to the first logic signal, and a second low-voltage pre-driving unit for generating a second control signal at a second node according to the second logic signal; and an output module, coupled to the first node and the second node of the pre-driving module, for generating an output signal having a third level range at an output node according to the first control signal and the second control signal; wherein each of the first level range and the second level range is smaller than the third level range.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an output buffer according to the prior art.

FIG. 2 is a schematic diagram of an output buffer according to an embodiment.

### DETAILED DESCRIPTION

An output buffer in the following embodiment is capable of maintaining output signal stability while meeting the trends for lower operating voltages. The following embodiment takes into consideration that during manufacturing process of Complementary Metal-Oxide-Semiconductor (CMOS), the weakening effect of driving currents due to a lower supply voltage level is less obvious for low-voltage transistors. Therefore, partial components in an output buffer that do not directly face the load are implemented with low-voltage components. As a result, a better noise toleration capability toward the power supply may be achieved for the output buffer. Also, a shorter output signal delay may be obtained, thus facilitating implementation of a low-jitter output signal.

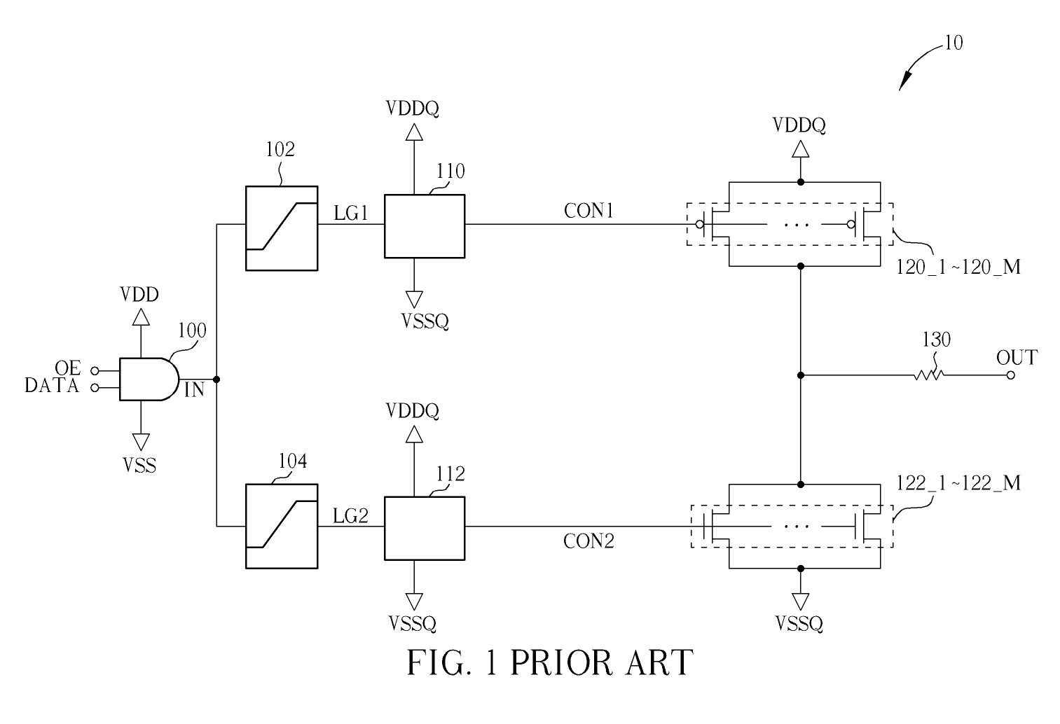

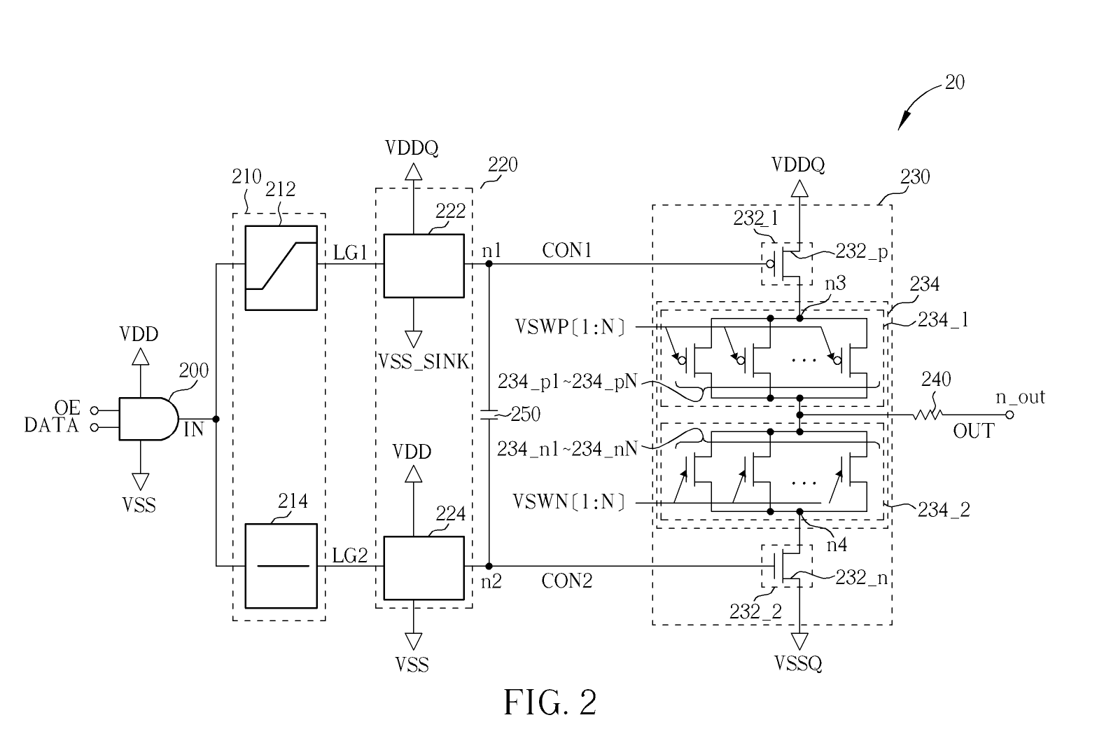

Please refer to FIG. 2, which is a schematic diagram of an output buffer 20 according to an embodiment. The output buffer 20 includes a logic unit 200, a level conversion module 210, a pre-driving module 220, an output module 230 and a resistor 240. Moreover, similar to the conventional output buffer 10 in FIG. 1, an input signal IN on the input side has an initial signal level range, which is also between an initial high voltage VDD and an initial low voltage VSS. An output signal OUT at an output node n_out has a third signal level range, which is also between a first high voltage VDDQ and a first low voltage VSSQ. However, an important distinction between the output buffer 20 and the output buffer 10 shown in FIG. 1 is that partial components that do not direct face the load in the pre-driving module 220 and the output module 230 are implemented with low-voltage thin-oxide components. Moreover, to suit the above-mentioned low-voltage structure, a level conversion range and structure of the level conversion module 210 are modified as well. The following describes structures and operations of each component in the output buffer 20.

The logic unit 200 is preferably an AND gate, for performing a logic AND operation on an enable signal OE and a data signal DATA, to decide whether to transmit the data signal DATA as an input signal IN according to the enable signal OE.

The level conversion module 210 is utilized for generating a first logic signal LG1 having a first level range and a second logic signal LG2 having a second level range according to the input signal IN. To implement the following pre-driving module 220 with low-voltage thin-oxide components, a unique feature of the level conversion module 210 is that the input signal IN does not need to be amplified, i.e. the level conversion range of the level conversion module 210 can be configured to be smaller than that in the prior art.

Specifically, unlike the prior art shown in FIG. 1, the level conversion module 210 does not convert both of the first logic signal LG1 and the second logic signal LG2 to the wide voltage level range as is supplied by the output module 230, i.e. the third level range (VDDQ-VSSQ). Instead, the first logic signal LG1 and the second logic signal LG2 are converted to a narrower first voltage level range and second voltage level range, respectively. In other words, both of the first level range of the first logic signal LG1 and the second level range of the second logic signal LG2 are smaller than the third level range of the output signal OUT.

Moreover, different from the prior art, each of the first level range of the first logic signal LG1 and the second level range of the second logic signal LG2 (VDD-VSS) is no longer required to be larger than the initial level range (VDD-VSS) of the input signal IN, and may be configured to be substantially smaller than or equal to the initial level range (VDD-VSS). Preferably, the level conversion module 210 may either follow the initial level range (LG2) or shift the initial level range (LG1) to drive the low-voltage thin-oxide components in the pre-driving module 220. In more detail, the first level range obtained after conversion may be set between a first high voltage VDDQ and a second low voltage VSS_SINK, wherein the first high voltage VDDQ and the second low voltage VSS_SINK must satisfy the condition (VDDQ-VSS_SINK≦VDD-VSS). For example, the first level range is obtained by shifting the initial level range, i.e. VSS_SINK is set to VDDQ-(VDD-VSS). Furthermore, the second level range can be set to be different from the first level range. For instance, the second level range can be set to follow (i.e. to be substantially equal to) the initial level range of the input signal IN, namely, between the initial high voltage VDD and the initial low voltage VSS.

FIG. 2 also shows an exemplary detailed structure of the level conversion module 210, for implementing the above-mentioned preferred level conversion range. As shown in FIG. 2, the level conversion module 210 includes a level conversion unit 212 and a delay unit 214. The level conversion unit 212 is utilized for performing level conversion on the input signal IN and generating the first logic signal LG1 having the first level range, wherein the first level range may be arranged to be between the first high voltage VDDQ and the second low voltage VSS_SINK, and must satisfy the condition (VDDQ-VSS_SINK≦VDD-VSS), e.g. VSS_SINK=VDDQ-(VDD-VSS). Furthermore, the delay unit 214 is utilized for delaying the input signal IN to generate the second logic signal LG2 having the second level range, wherein the second level range may be arranged to be between the initial high voltage VDD and the initial low voltage VSS.

The pre-driving module 220 can be composed of inverters or multi-stage amplifiers connected in series. A unique feature of the pre-driving module 220 is that unlike the prior art shown in FIG. 1, which implements the pre-driving units 110 and 112 with high-voltage thick oxide transistors, the pre-driving module 220 is implemented with low-voltage thin-oxide transistors, and thus has a smaller operating voltage range. The pre-driving module 220 is utilized for generating a first control signal CON1 at a first node n1 and generating a second control signal CON2 at a second node n2 according to the first logic signal LG1 and the second logic signal LG2, respectively. The embodiment in FIG. 2 further shows an exemplary detailed structure of the pre-driving module 220, wherein the pre-driving module 220 may include a first low-voltage pre-driving unit 222 and a second low-voltage pre-driving unit 224. The first low-voltage pre-driving unit 222 outputs the first high voltage VDDQ or the second low voltage VSS_SINK to the first node n1 as the first control signal CON1 according to the first logic signal LG1. The second low-voltage pre-driving unit 224 outputs the initial high voltage VDD or the initial low voltage VSS to the second node n2 as the second control signal CON2 according to the second logic signal LG2.

The output module 230 generates the output signal OUT having the third level range (VDDQ-VSSQ) at the output node n_out according to the first control signal CON1 and the second control signal CON2. The resistor 240 is used for providing electrostatic discharge (ESD) delay protection. The embodiment of FIG. 2 further shows an exemplary detailed structure of the output module 230, wherein the output module 230 includes a low-voltage output unit and a high voltage programmable unit 234. The low-voltage output unit does not directly face the load, and therefore can be composed of low-voltage transistors. The high voltage programmable unit 234 directly faces the load, and is therefore composed of high-voltage transistors.

The low-voltage output unit includes a first output block 232_1 and a second output block 232_2, composed of a first type low-voltage transistor 232_{—}p (e.g. a P-type transistor) and a second type low-voltage transistor 232_{—}n (e.g. an N-type transistor), respectively. The first output block 232_1 and the second output block 232_2 receive controls of the first control signal CON1 and the second control signal CON2 to decide whether the first high voltage VDDQ is transmitted to the output node n_out, and to decide whether the first low voltage VSSQ is transmitted to the output node n_out.

Furthermore, the high voltage programmable unit 234 includes a first programmable control block 234_1 and a second programmable control block 234_2, composed of one or more first type high-voltage transistors 234_p1-234_pN and one or more second type high-voltage transistors 234_n1-234_nN, respectively. The first programmable control block 234_1 and the second programmable control block 234_2 are coupled between the low-voltage output unit and the output node n_out, for receiving controls of a first programmable signal VSWP[1:N] and a second programmable signal VSWN[1:N] to decide whether a connection between the first type low-voltage transistor 232_{—}p and the output node n_out is conducted, and to decide whether a connection between the second type low-voltage transistor 232_{—}n and the output node n_out is conducted. Via controlling a number of conducting transistors among the high-voltage transistors 234_p1-234_pN and 234_n1-234_nN, it is possible to use the first programmable signal VSWP[1:N] and the second programmable signal VSWN[1:N] to control an output impedance of the output buffer 20, thereby controlling the level of the output signal OUT.

Note that, in the above embodiment, only the load-facing high voltage programmable unit 234 in the output buffer 20 is implemented with high-voltage components, and both the pre-driving module 220 and the low-voltage output unit are implemented with low-voltage components instead. Since the high voltage programmable unit 234 directly facing the load is implemented with high-voltage components, it is therefore possible to prevent punch-through effect in the output stage, or prevent reliability problems arising from variations in the level of the output signal OUT indifferent applications. Moreover, since the pre-driving module 220 and the low-voltage output unit are now implemented with low-voltage components, the output buffer 20 would have a higher noise tolerance toward the power supply. In turn, it is possible to achieve a shorter delay time of the output signal OUT, facilitating implementation of low-jitter requirements for the output signal OUT.

Furthermore, note that for the output module 230, only one of either an upper-bridge circuit (232_1, 234_1) or a lower-bridge circuit (232_2, 234_2) is conducted at any given time. Therefore, the first control signal CON1 and the second control signal CON2 must be kept in opposite phases. To this end, the output buffer 20 is preferably further incorporated with a coupling capacitor 250 coupled between the first node n1 and the second node n2, so as to synchronize switching operations of the first control signal CON1 and the second control signal CON2, thereby increasing a duty cycle of the output signal OUT.

In the prior art, most of the pre-driving unit 110, 112 and the output transistor arrays 1201-120M, 1221-122M in the output buffer 10 are implemented with high voltage component. As a result, when the operating voltage decreases, normal operation may be undermined due to a higher jitter in the output signal OUT, or due to a higher threshold voltage (Vth) in the high-voltage components. Comparatively, only the load-facing high voltage programmable unit 234 in the output buffer 20 is implemented with high voltage components, whereas the pre-driving module 220 and the low-voltage output unit are both implemented with low-voltage components instead. Therefore, for low operating voltages, a stable output signal OUT may be maintained.

In summary, the embodiments of the present invention replace high voltage components with low-voltage components for the driving stage and output stage of the output buffer, such that the output signal may be kept stable while fulfilling the demand for lower operating voltages.

Those skilled in the art will readily observe that numerous modifications and alterations of the device and method may be made while retaining the teachings of the invention.

What is claimed is:

1. An output buffer, comprising:
a level conversion module, for generating a first logic signal having a first level range and a second logic signal having a second level range according to an input signal;
a pre-driving module, composed of low-voltage transistors, for generating a first control signal at a first node and generating a second control signal at a second node according to the first logic signal and the second logic signal; and
an output module, coupled to the first node and the second node of the pre-driving module, for generating an output signal having a third level range at an output node according to the first control signal and the second control signal;
wherein each of the first level range and the second level range is smaller than the third level range.

2. The output buffer of claim 1, wherein the first level range is different from the second level range.

3. The output buffer of claim 1, wherein each of the first and second level ranges is substantially smaller than or equal to an initial level range of the input signal.

4. The output buffer of claim 1, wherein an initial level range of the input signal is between an initial high voltage and an initial low voltage, the third level range is between a first high voltage and a first low voltage, the first level range is between the first high voltage and a second low voltage different from the first low voltage, and the second level range is between the initial high voltage and the initial low voltage.

5. The output buffer of claim 4, wherein the second low voltage is substantially equal to the first high voltage—(the initial high voltage—the initial low voltage).

6. The output buffer of claim 1, wherein the output module comprises:
a low-voltage output unit, composed of low-voltage transistors, for receiving controls of the first control signal and the second control signal, to decide whether a first high voltage source is coupled to the output node, and to decide whether a first low voltage source is coupled to the output node.

7. The output buffer of claim 6, wherein the output module further comprises:
a high-voltage programmable unit, composed of high-voltage transistors, and having a third node and a fourth node coupled to the low-voltage output unit, for receiving controls of a first programmable signal and a second programmable signal, to decide whether a connection between the third node and the output node is conducted, and to decide whether a connection between the fourth node and the output node is conducted.

8. The output buffer of claim 6, wherein the low-voltage output unit comprises:
a first output block, comprising a first type of low-voltage transistor coupled in parallel between the first high voltage source and a third node, for receiving control of the fist control signal to conduct or cut off; and
a second output block, comprising a second type low-voltage transistor coupled in parallel between the first low voltage source and a fourth node, for receiving control of the second control signal to conduct or cut off.

9. The output buffer of claim 7, wherein the high voltage programmable unit comprises:
a first programmable control block, comprising one or more first type high-voltage transistors coupled in parallel between the third node and the output node, for receiving control of the first programmable signal to conduct or cut off; and
a second programmable control block, comprising one or more second type high-voltage transistors coupled in parallel between the fourth node and the output node, for receiving control of the second programmable signal to conduct or cut off.

10. The output buffer of claim 1, wherein the level conversion module comprises:
a level conversion unit, coupled to a logic unit, for performing level conversion on the input signal to generate the first logic signal having the first level range; and
a delay unit, coupled to the logic unit, for delaying the input signal to generate the second logic signal having the second level range.

11. The output buffer of claim 1, wherein the pre-driving module comprises:
a first low-voltage pre-driving unit, coupled between a first high voltage source and a second low voltage source, for generating the first control signal at the first node according to the first logic signal; and
a second low-voltage pre-driving unit, coupled between an initial high voltage source and an initial low voltage source, for generating the second control signal at the second node according to the second logic signal.

12. The output buffer of claim 1 further comprising a coupling capacitor, coupled between the first node and the second node, for increasing a duty cycle of the output signal.

13. An output buffer, comprising:
a level conversion module, for generating a first logic signal having a first level range and a second logic signal having a second level range according to an input signal;
a pre-driving module, composed of low-voltage transistors, for generating a first control signal at a first node and generating a second control signal at a second node according to the first logic signal and the second logic signal; and
an output module, coupled to the first node and the second node of the pre-driving module, for generating an output signal having a third level range at an output node according to the first control signal and the second control signal; wherein the first level range is different from the second level range, each of the first level range and the second level range is smaller than the third level range, and each of the first and second level ranges is substantially smaller than or equal to an initial level range of the input signal.

14. The output buffer of claim 13, wherein the initial level range of the input signal is between an initial high voltage and an initial low voltage, the third level range is between a first high voltage and a first low voltage, the first level range is between the first high voltage and a second low voltage different from the first low voltage, and the second level range is between the initial high voltage and the initial low voltage.

15. An output buffer, comprising:
a level conversion module, comprising a level conversion unit for performing level conversion on an input signal to generate a first logic signal having a first level range; and a delay unit for delaying the input signal to generate a second logic signal having a second level range;
a pre-driving module, comprising a first low-voltage pre-driving unit for generating a first control signal at a first node according to the first logic signal, and a second low-voltage pre-driving unit for generating a second control signal at a second node according to the second logic signal; and
an output module, coupled to the first node and the second node of the pre-driving module, for generating an output signal having a third level range at an output node according to the first control signal and the second control signal; wherein each of the first level range and the second level range is smaller than the third level range.

16. The output buffer of claim 15, wherein the first level range is different from the second level range.

17. The output buffer of claim 15, wherein each of the first and second level ranges is substantially smaller than or equal to an initial level range of the input signal.

18. The output buffer of claim 15, wherein an initial level range of the input signal is between an initial high voltage and an initial low voltage, the third level range is between a first high voltage and a first low voltage, the first level range is between the first high voltage and a second low voltage different from the first low voltage, and the second level range is between the initial high voltage and the initial low voltage.
